(19) United States
(12) Patent Application Publication
(10) Pub. No.: US 2026/0196739 A1
(43) Pub. Date: Jul. 9, 2026

(54) BASE STATION ANTENNAS HAVING CABLELESS PHASE SHIFTERS WITH INTEGRATED FEED STALKS

(71) Applicant: Outdoor Wireless Networks LLC, Richardson, TX (US)

(72) Inventors: Nagaraju Mondi, Salcette Goa (IN); Sekharbabu Bunga, Salcette GOA (IN); Kumara Swamy Kasani, Salcette Goa (IN); Ligang Wu, Suzhou (CN)

(21) Appl. No.: 19/436,009

(22) Filed: Dec. 30, 2025

(30) Foreign Application Priority Data
Jan. 3, 2025 (CN) 2025100093305

(51) Int. Cl. H01Q 19/10; H01Q 1/24; H01Q 3/36; H01Q 9/16; H01Q 21/06

(52) U.S. Cl. CPC H01Q 19/108; H01Q 1/246; H01Q 3/36; H01Q 9/16; H01Q 21/062

(57) ABSTRACT

A base station antenna comprises a reflector, a first RF port, a first array of radiating elements that extends in a longitudinal direction, and a first printed circuit board that comprises a first dielectric substrate and a plurality of first metal traces on a first major surface of the first dielectric substrate, the first metal traces implementing a portion of a first phase shifter, the first printed circuit board comprising a first part that is mounted behind the reflector and a plurality of second parts that extend forwardly through one or more first openings in the reflector.

### CROSS-REFERENCE TO RELATED APPLICATION

The present application claims priority to Chinese Patent Application Serial No. 202510009330.5, filed Jan. 3, 2025, the entire content of which is incorporated herein by reference as if set forth in its entirety.

### FIELD

The present disclosure relates to communications systems and, in particular, to base station antennas for cellular communications systems.

### BACKGROUND

Cellular communications systems are well known in the art. In a cellular communications system, a geographic area is divided into regions that are referred to as “cells” which are served by respective base stations. Each base station may include one or more base station antennas that are configured to provide two-way radio frequency (“RF”) communications with mobile subscribers that are within the cell served by the base station. Typically, the base station antennas are mounted on a tower or other raised structure, with the radiation patterns (also referred to herein as “antenna beams”) that are generated by the base station antennas directed outwardly.

A common base station configuration is the three sector configuration in which a cell is divided into three 120° “sectors” in the azimuth (horizontal) plane, where the sectors typically are hexagonally-shaped in top-down view. A separate base station antenna provides coverage (service) to each sector. Typically, each base station antenna will include multiple vertically-extending columns of radiating elements that are typically referred to as “linear arrays.” Linear arrays may be straight columns of radiating elements or columns in which some of the radiating elements are staggered horizontally to narrow the beamwidths of the generated antenna beams in the azimuth (horizontal) plane. Most modern base station antennas include both “low-band” linear arrays of radiating elements that support service in some or all of the 617-960 MHz frequency band and “mid-band” linear arrays of radiating elements that support service in some or all of the 1427-2690 MHz frequency band. The above-described linear arrays are typically formed using dual-polarized radiating elements, which allows each linear array to transmit and receive RF signals at two orthogonal polarizations (i.e., an antenna beam is generated at each polarization). The dual-polarized radiating elements typically are implemented as slant −/+45° radiating elements that have a first radiator that transmits and receives RF radiation having a −45° linear polarization and a second radiator that transmits and receives RF radiation having a +45° linear polarization.

Each linear array of dual-polarized radiating elements is coupled to two ports of a radio (one port for each polarization). An RF signal that is to be transmitted at a first polarization (e.g., slant +45° polarization) by one of the linear arrays is passed from the radio to the antenna where it is divided into a plurality of sub-components, with each sub-component fed to the first polarization radiators in a respective subset of the radiating elements in the linear array (typically each sub-component is fed to between one and three radiating elements). The sub-components of the RF signal are transmitted through the first polarization radiators of the radiating elements to generate a first polarization antenna beam that covers a generally fixed coverage area, such as a 120° sector of a cell. Typically these linear arrays will have remote electronic tilt (“RET”) capabilities which allow a cellular network operator to electronically change, from a remote location such as a control center, the pointing angle of the generated antenna beams in the elevation (vertical) plane (i.e., the downtilt angles of the antenna beams). By electronically changing the downtilt angle of the antenna beams, a cellular network operator can effectively change the size of the sector served by the antenna since the downtilt angle determines how far the antenna beams extend from the base station.

The downtilt angle of an antenna beam generated by a linear array may be electronically changed by applying a phase taper across the radiating elements of the array. Such a phase taper may be applied by adjusting the settings on a phase shifter that is positioned along the RF transmission path between a radio and the individual radiating elements of the array. One widely-used type of phase shifter is a rotary arc wiper phase shifter that includes a main printed circuit board and a “wiper” printed circuit board that may be rotated relative to the main printed circuit board. An arc wiper phase shifter includes one or more power dividers that are configured to divide an input RF signal that is received at the main printed circuit board of the phase shifter into a plurality of sub-components, and to then capacitively couple at least some of these sub-components to the wiper printed circuit board. The sub-components of the RF signal that are capacitively coupled to the wiper printed circuit board are capacitively coupled from the wiper printed circuit board back to the main printed circuit board along one or more arc-shaped traces, where each arc has a different diameter. Each end of each arc-shaped trace may be connected to a radiating element or to a sub-array of radiating elements. By physically (mechanically) rotating the wiper printed circuit board relative to the main printed circuit board, the locations where the sub-components of the RF signal capacitively couple back to the main printed circuit board may be changed, which thus changes the length of the respective transmission path from the phase shifter to an associated radiating element for each sub-component of the RF signal. The changes in these path lengths result in changes in the phases of the respective sub-components of the RF signal, and since the arcs have different radii, the phase changes along the different paths will be different. Thus, the above-described wiper phase shifters may be used to apply a phase taper to the sub-components of an RF signal that are applied to each radiating element (or sub-group of radiating elements). The wiper printed circuit board is typically moved using an electromechanical actuator such as a DC motor that is connected to the wiper printed circuit board via a mechanical linkage.

FIG. 1 is a schematic perspective view of a conventional dual rotary arc wiper phase shifter assembly 1. Phase shifters are often implemented in pairs with a phase shifter for each polarization RF signal of a linear array, as the same amount of downtilt is applied to each polarization antenna beam generated by a linear array. The dual rotary arc wiper phase shifter assembly 1 includes first and second phase shifters 2, 2A that each divide an input RF signal into five sub-components and apply a phase taper across those sub-components. Operation of phase shifter 2 will be described with respect to a transmit (downlink) RF signal. It will be appreciated that the phase shifters 2, 2A will also apply phase tapers to uplink RF signals that are received by their associated linear array.

As shown in FIG. 1, the dual phase shifter assembly 1 includes first and second main (stationary) printed circuit boards 10, 10A that are arranged back-to-back as well as first and second rotatable wiper printed circuit boards 20, 20A (wiper printed circuit board 20A is barely visible in the view of FIG. 1) that are pivotally and rotatably mounted on the respective main printed circuit boards 10, 10A via a pivot pin 22. The wiper printed circuit boards 20, 20A are joined together at their distal ends via a bracket 24. The position of each rotatable wiper printed circuit board 20, 20A relative to its respective main printed circuit board 10, 10A is controlled by the position of a mechanical linkage 26 (partially shown in FIG. 1) that extends between an output member of a RET actuator and the dual phase shifter assembly 1. The description of dual phase shifter assembly 1 will focus on operation of the first phase shifter 2 implemented via main printed circuit board 10 and wiper printed circuit board 20. It will be appreciated that the second phase shifter 2A operates in identical fashion.

Main printed circuit board 10 includes an input port 30 and five output ports 40-1 through 40-5. Output ports 40-1, 40-2, 40-4 and 40-5 comprise the ends of a pair of concentric, arcuate transmission line traces 12, 14. A third transmission line trace 16 on main printed circuit board 10 connects the input port 30 to output port 40-3. An input RF transmission line 32 on main printed circuit board 10 connects the input port 30 to a pad (not visible in FIG. 1) that is positioned underneath the wiper printed circuit board 20. RF signals on the input trace 32 are capacitively coupled to a corresponding facing pad (not visible in FIG. 1) on the wiper printed circuit board 20. The wiper printed circuit board 20 includes a power divider that receives these capacitively coupled signals and divides them into two sub-components that are coupled to first and second additional arc-shaped pads (not visible in FIG. 1) that overlap the arcuate traces on the main printed circuit board 10. The two sub-components are capacitively coupled from the two arc-shaped pads on the wiper printed circuit board 20 to the respective arc-shaped transmission line traces 12, 14 on the main printed circuit board 10, where each sub-component splits so that the two halves of the first sub-component flow to the respective output pads 40-2, 40-4 at the ends of the inner arc-shaped trace 12 and so that the two halves of the second sub-component flow to the respective output pads 40-1, 40-5 at the ends of the outer arc-shaped trace 14. A respective coaxial cable 90 is connected to each output port 40. Each coaxial cable 90 connects to the first polarization radiators of a sub-array of one or more radiating elements in the linear array. As the wiper printed circuit board 20 moves, an electrical path length from the input port 30 of phase shifter 2 to output ports 40-1, 40-2, 40-4, 40-5 changes. For example, as the wiper printed circuit board 20 moves to the left it shortens the electrical length of the path from the input port 30 to the output ports 40-2, 40-4 connected to the left sides of transmission line traces 12, 14, while the electrical length from the input port 30 to the output ports 40-1, 40-5 connected to the right sides of transmission line traces 12, 14 increases by a corresponding amount. These changes in path lengths apply a phase taper to the sub-components of the input RF signal that are output from phase shifter 2, with the sub-components output at output ports 40-1 through 40-5 having relative phases of 2X°, −X°, 0°, X° and 2X°, respectively, where the value of X is set by how far the wiper printed circuit board is rotated to the left or right.

### SUMMARY

Pursuant to some embodiments of the present invention, base station antennas are provided that comprise a reflector, a first RF port, a first array of radiating elements that extends in a longitudinal direction, and a first printed circuit board. The first printed circuit board comprises a first dielectric substrate and a plurality of first metal traces on a first major surface of the first dielectric substrate, the first metal traces implementing a portion of a first phase shifter. The first printed circuit board has a first part that is mounted behind the reflector and a plurality of second parts that extend forwardly through one or more first openings in the reflector.

In some embodiments, the plurality of second parts comprise a plurality of first polarization feed stalks for respective ones of at least four of the radiating elements in the first array of radiating elements. In some embodiments, the first RF port is coupled to an input of the first phase shifter and a first of a plurality of outputs of the first phase shifter is coupled to a first signal trace that is on a first of the first polarization feed stalks and a second of the plurality of outputs of the first phase shifter is coupled to a second signal trace that is on a second of the first polarization feed stalks.

In some embodiments, the base station antenna further comprises a second RF port and a second printed circuit board that comprises a second dielectric substrate and a plurality of second metal traces on a first major surface of the second dielectric substrate, the second metal traces implementing a portion of a second phase shifter, the second printed circuit board comprising a third part that is mounted behind the reflector and a plurality of fourth parts that extend forwardly through one or more second openings in the reflector. In some embodiments, the first dielectric substrate has a second major surface with a metal ground plane thereon. In some embodiments, a length of the first printed circuit board in the longitudinal direction is at least 80% a length of the first array in the longitudinal direction.

In some embodiments, the plurality of fourth parts comprise a plurality of second polarization feed stalks for the respective radiating elements in the first array of radiating elements. In some embodiments, the second RF port is coupled to an input of the second phase shifter and a first of a plurality of outputs of the second phase shifter is coupled to a third signal trace that is on a first of the second polarization feed stalks and a second of the plurality of outputs of the second phase shifter is coupled to a fourth signal trace that is on a second of the second polarization feed stalks. In some embodiments, each radiating element in the first array of radiating elements comprises a feed stalk structure that includes a respective one of the first polarization feed stalks and a respective one of the second polarization feed stalks.

In some embodiments, centers of the first and second polarization feed stalks that form each feed stalk structure are offset in the longitudinal direction. In some embodiments, metallization of the first and second polarization feed stalks of a first of the radiating elements do not overlap in a transverse direction that is perpendicular to the longitudinal direction and to a forward direction of the base station antenna. In some embodiments, each radiating element further comprises a respective dipole radiator printed circuit board that includes a first slot that receives a forward end of a respective one of the first polarization feed stalks and a second slot that receives a forward end of a respective one of the second polarization feed stalks.

In some embodiments, a first ground plane is provided on a second major surface of the first dielectric substrate and a second ground plane is provided on a second major surface of the second dielectric substrate. In some embodiments, the first printed circuit board and the second printed circuit board are mounted back-to-back with the first ground plane facing the second ground plane. In some embodiments, a solder mask is interposed between the first ground plane and the second ground plane.

In some embodiments, an end radiating element in the first array of radiating elements that is at either end of the first array of radiating elements is electrically connected to the first printed circuit board through a cable. In some embodiments, the first printed circuit board and the reflector both have longitudinal axes that extend in the longitudinal direction, with the printed circuit board defining a first plane and the reflector defining a second plane that is perpendicular to the first plane.

In some embodiments, the base station antenna further comprises a third printed circuit board that is electrically connected to the first printed circuit board through one or more jumpers, where the third printed circuit board comprises a third dielectric substrate and a plurality of third metal traces on a first major surface of the third dielectric substrate, the third printed circuit board comprising a fifth part that is mounted behind the reflector and a plurality of sixth parts that extend forwardly through one or more third openings in the reflector.

Pursuant to further embodiments of the present invention, base station antennas are provided that comprise a reflector that has a top end and a bottom end that are separated from each other in a longitudinal direction of the base station antenna and a first side and a second side that are separated from each other in a transverse direction that is perpendicular to the longitudinal direction and a first dual-polarized radiating element that has first and second dipole radiators that are positioned forwardly of the reflector. The first dual-polarized radiating element comprises a first polarization feed stalk that has a first dielectric substrate that has a first major surface and a second major surface, the first polarization feed stalk having a first longitudinal axis that extends in a forward direction that is perpendicular to both the longitudinal direction and the transverse direction and a second polarization feed stalk that has a second dielectric substrate that has a first major surface and a second major surface, the second polarization feed stalk having a second longitudinal axis that extends in the forward direction. The first major surface of the first dielectric substrate extends in parallel to the first major surface of the second dielectric substrate. Additionally, metallization on the first dielectric substrate does not overlap metallization on the second dielectric substrate in the transverse direction.

In some embodiments, the first dual-polarized radiating element further comprises a dipole radiator printed circuit board that includes a first slot that receives a forward end of the first polarization feed stalk and a second slot that receives a forward end of the second polarization feed stalk.

In some embodiments, the first dual-polarized radiating element further comprises a dipole radiator printed circuit board that includes a first slot that receives a forward end of the first polarization feed stalk and a forward end of the second polarization feed stalk.

In some embodiments, first microstrip transmission lines are provided on the first major surface of the first dielectric substrate, a first ground plane is provided on the second major surface of the first dielectric substrate, second microstrip transmission lines are provided on the first major surface of the second dielectric substrate, and a second ground plane is provided on the second major surface of the second dielectric substrate.

In some embodiments, the first polarization feed stalk is part of a first printed circuit board that includes first metal traces that implement a portion of a first phase shifter, and the second polarization feed stalk is part of a second printed circuit board that includes second metal traces that implement a portion of a second phase shifter. In some embodiments, a distal end of the first polarization feed stalk is positioned forwardly of the reflector and the first metal traces that implement the portion of the first phase shifter are positioned rearwardly of the reflector. In some embodiments, the first polarization feed stalk extends through an opening in the reflector. In some embodiments, the first printed circuit board and the second printed circuit board are mounted back-to-back with a solder mask interposed therebetween. In some embodiments, the first polarization feed stalk and the second polarization feed stalk do not overlap in the transverse direction. In some embodiments, an output of the first phase shifter is directly connected to a signal trace on the first polarization feed stalk via a microstrip transmission line.

Pursuant to other embodiments of the present invention, base station antennas are provided that comprise a reflector that has a top end and a bottom end that are separated from each other in a longitudinal direction of the base station antenna and a first side and a second side that are separated from each other in a transverse direction that is perpendicular to the longitudinal direction and a first dual-polarized radiating element that has first and second dipole radiators that are positioned forwardly of the reflector. The first dual-polarized radiating element comprises a first polarization feed stalk that has a first dielectric substrate that has a first major surface and a second major surface, the first polarization feed stalk having a first longitudinal axis that extends in a forward direction that is perpendicular to both the longitudinal direction and the transverse direction, a second polarization feed stalk that has a second dielectric substrate that has a first major surface and a second major surface, the second polarization feed stalk having a second longitudinal axis that extends in the forward direction, and a dipole radiator printed circuit board mounted on the first polarization feed stalk and the second polarization feed stalk. The first major surface of the first dielectric substrate extends in parallel to the first major surface of the second dielectric substrate.

In some embodiments, metallization on the first dielectric substrate does not overlap metallization on the second dielectric substrate in the transverse direction. In some embodiments, the first polarization feed stalk comprises a first tab that extends through the dipole radiator printed circuit board and the second polarization feed stalk comprises a second tab that extends through the dipole radiator printed circuit board, where a center of the first tab is offset from a center of the second tab in the longitudinal direction.

In some embodiments, first microstrip transmission lines are provided on the first major surface of the first dielectric substrate, a first ground plane is provided on the second major surface of the first dielectric substrate, second microstrip transmission lines are provided on the first major surface of the second dielectric substrate, and a second ground plane is provided on the second major surface of the second dielectric substrate. In some embodiments, the first polarization feed stalk is part of a first printed circuit board that includes first metal traces that implement a portion of a first phase shifter, and the second polarization feed stalk is part of a second printed circuit board that includes second metal traces that implement a portion of a second phase shifter. In some embodiments, a distal end of the first polarization feed stalk is positioned forwardly of the reflector and the first metal traces that implement the portion of the first phase shifter are positioned rearwardly of the reflector. In some embodiments, the first polarization feed stalk extends through an opening in the reflector. In some embodiments, the first printed circuit board and the second printed circuit board are mounted back-to-back with a solder mask interposed therebetween. In some embodiments, an output of the first phase shifter is directly connected to a signal trace on the first polarization feed stalk via a microstrip transmission line.

Pursuant to additional embodiments of the present invention, base station antennas are provided that comprise a reflector, a first array of radiating elements that extends in a longitudinal direction, where each of the radiating elements includes a respective pair of dipole radiators and a respective feed stalk structure that mounts the pair of dipole radiators forwardly of the reflector, and a first printed circuit board that comprises a first part that is mounted behind the reflector and a plurality of second parts that extend forwardly through one or more first openings in the reflector. A first of the second parts forms part of the feed stalk structure for a first of the radiating elements and a second of the second parts forms part of the feed stalk structure for a second of the radiating elements.

In some embodiments, the first printed circuit board comprises a first dielectric substrate and a plurality of first metal traces on a first major surface of the first dielectric substrate, the first metal traces implementing a portion of a first phase shifter.

In some embodiments, the base station antenna may further comprise a second printed circuit board that comprises a third part that is mounted behind the reflector and a plurality of fourth parts that extend forwardly through the reflector, wherein a first of the fourth parts forms part of the feed stalk structure for the first of the radiating elements and a second of the fourth parts forms part of the feed stalk structure for the second of the radiating elements. In some embodiments, the second printed circuit board comprises a second dielectric substrate and a plurality of second metal traces on a first major surface of the second dielectric substrate, the second metal traces implementing a portion of a second phase shifter. In some embodiments, a center of the first of the second parts is offset in the longitudinal direction from a center of the first of the fourth parts. In some embodiments, metallization on the first of the second parts does not overlap metallization on the first of the fourth parts in a transverse direction that is perpendicular to the longitudinal direction and to a forward direction of the base station antenna.

### BRIEF DESCRIPTION OF THE DRAWINGS

FIG. 1 is a perspective view of a pair of conventional arc rotary electromechanical phase shifters.

FIG. 2A is a schematic front view of a conventional multiband base station antenna with the radome removed.

FIG. 2B is a schematic view illustrating the connections between one phase shifter and the radiating elements in one of the linear arrays in the base station antenna of FIG. 2A.

FIG. 3A is a front perspective view of a multiband base station antenna according to embodiments of the present invention.

FIG. 3B is a schematic front view of a base station antenna of FIG. 3A with the radome removed.

FIG. 4A is a collage that includes right side and left side perspective views that illustrate the main printed circuit boards and radiating elements of one of the linear array assemblies of the base station antenna of FIG. 3A.

FIG. 4B is an end view of the two main printed circuit boards shown in FIG. 4A with a wiper support mounted thereon

FIG. 4C is an enlarged perspective view of a middle portion of the two main printed circuit boards shown in FIG. 4A with the wiper support mounted thereon.

FIG. 4D is a schematic view of one of the main printed circuit boards of the linear array assembly of FIG. 4A.

FIG. 5A is a right side view of one of the radiating elements included in one of the mid-band linear array assemblies of FIG. 3B.

FIG. 5B is a left side view of the radiating element of FIG. 5A.

FIG. 5C is a top side view of the radiating element of FIG. 5A.

FIG. 5D is a plan view of a dipole radiator printed circuit board of the radiating element of FIG. 5A.

FIG. 6A is a top view one of the mid-band linear array assemblies of FIG. 3B installed in a base station antenna.

FIGS. 6B and 6C are schematic left and right side views of the linear array assembly of FIG. 6A mounted on the reflector of the base station antenna.

FIG. 7 is a schematic perspective view of an alternative mid-band linear array assembly according to embodiments of the present invention that uses a shorter main printed circuit board and connects the outer radiating elements in the array to the main printed circuit board using jumper cables.

FIG. 8 is a schematic perspective view of another alternative mid-band linear array assembly according to embodiments of the present invention that replaces each main printed circuit board of the mid-band linear array assembly of FIG. 4A with three shorter main printed circuit boards that are interconnected to each other using jumper printed circuit boards.

It should be noted that herein reference numerals that include two numbers separated by a dash may be used, and that like elements may be referred to individually by their full reference numeral and may be referred to collectively by the first part of their reference numeral.

### DETAILED DESCRIPTION

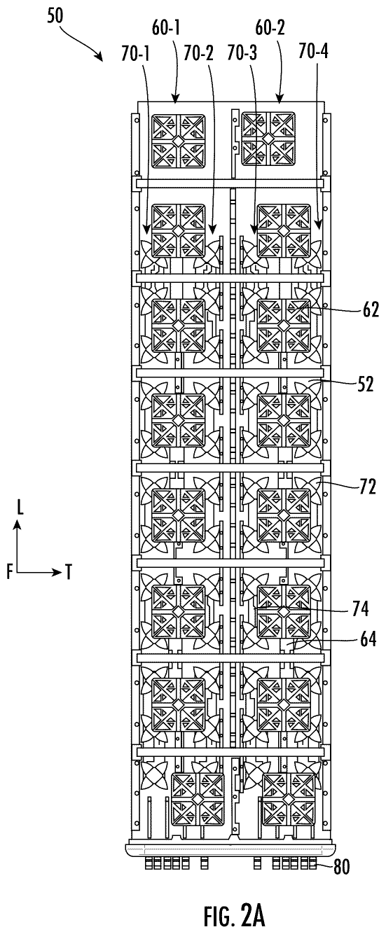

FIG. 2A is a schematic front view of a conventional multiband base station antenna 50. In FIG. 2A, a radome of the base station antenna 50 is removed to show an antenna assembly of the antenna 50. The axes in FIG. 2A illustrate the longitudinal (L), transverse (T) and forward (F) directions of base station antenna 50. In the description that follows, each antenna will be described using terms that assume that the antenna is mounted for use on a tower with the longitudinal axis L of the antenna extending in a vertical direction that is perpendicular to a plane defined by the horizon with the front surface of the antenna mounted opposite the tower pointing toward the coverage area for the antenna. It will be appreciated, however, that the base station antenna may be uptilted or downtilted to a degree when mounted so that the longitudinal axis is angled from the vertical direction.

As shown in FIG. 2A, base station antenna 50 includes a reflector 52. The reflector 52 may serve as both a structural component for the antenna assembly and as a ground plane and reflector for at least some of the radiating elements (discussed below) of antenna 50. The reflector 52 includes a generally flat metallic surface that extends in the longitudinal direction L of the antenna 50. Various mechanical and electronic components of base station antenna 50 (not shown) are mounted behind the reflector 52.

The base station antenna 50 further includes two low-band arrays 60-1, 60-2 of low-band radiating elements 62 and four mid-band arrays 70-1 through 70-4 of mid-band radiating elements 72. The low-band arrays 60 and mid-band arrays 70 are each implemented as longitudinally-extending linear arrays of radiating elements. Each of the low-band and mid-band linear arrays 60, 70 are passive arrays that generate static antenna beams that provide coverage to a predefined coverage area (e.g., antenna beams that are each configured to cover a 120° sector of a base station), with the only change to the coverage area occurring when the electronic downtilt angles of the generated antenna beams are adjusted (e.g., to change the size of the cell).

The low-band radiating elements 62 are configured to transmit and receive signals in the 617-960 MHz frequency range or a portion thereof (e.g., the 617-896 MHz frequency band, the 696-960 MHz frequency band, etc.). The mid-band radiating elements 72 are configured to transmit and receive signals in the 1427-2690 MHz frequency range or a portion thereof (e.g., the 1695-2690 MHz frequency band). The radiating elements 62, 72 are mounted to extend forwardly from the reflector 52.

The low-band and mid-band radiating elements 62, 72 may be implemented as dual-polarized radiating elements that each include first and second radiators that are configured to transmit and receive RF energy at orthogonal polarizations. For example, the low-band and mid-band radiating elements 62, 72 may be implemented as slant −45°/+45° cross-dipole radiating element that include a −45° dipole radiator and a +45° dipole radiator.

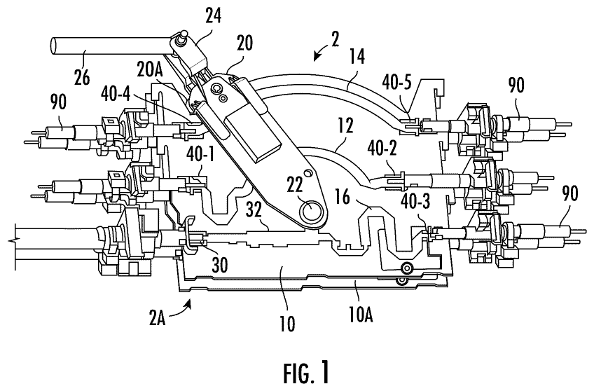

Base station antenna 50 further includes a plurality of RF ports 80. Four of the RF ports 80 may be coupled (e.g., via coaxial cables) to four ports of a low-band radio, and the remaining eight RF ports 80 may be coupled (e.g., via coaxial cables) to the four ports of two mid-band radios. Since dual-polarized radiating elements are used, each of the low-band and mid-band linear arrays 60, 70 is connected to a pair of the RF ports 80. For example, a first feed cable and a first feed network connects a first of the RF ports 80 to the first polarization radiators of the mid-band radiating elements 72 in the first mid-band linear array 70-1, and a second feed cable and a second feed network connect a second of the RF ports 80 to the second polarization radiators of the mid-band radiating elements 72 in the first mid-band linear array 70-1. RF signals that are to be transmitted by mid-band linear array 70-1 are passed from the mid-band radio to the first and second of the RF ports 80 to the associated feed networks. The feed network for the first mid-band linear array 70-1 includes a phase shifter assembly 1 (not visible in FIG. 2A, but see FIG. 1) that includes first and second phase shifters 2, 2A. The outputs 40 of phase shifter 2 are connected to the first polarization dipole radiators of respective sub-arrays of one or more of the radiating elements 72 in the first linear array 70-1, and the outputs 40A of the second phase shifter 2A are connected to the second polarization dipole radiators of respective sub-arrays of one or more radiating elements 72 in the first linear array 70-1. The sub-components of a first RF signal that are radiated into free space by the first polarization dipole radiators form a first polarization antenna beam, and the sub-components of a second RF signal that are radiated into free space by the second polarization dipole radiators form a second polarization antenna beam. Each antenna beam may be configured to provide coverage to approximately 120° in the azimuth plane so that the base station antenna 50 may act as a sector antenna for a three-sector base station. Each of the other linear arrays 60, 70 in base station 50 may similarly includer feed networks that have a pair of phase shifters configured in the same manner.

FIG. 2B is a schematic view illustrating the connections between phase shifter 2 and the first polarization radiators of the radiating elements 72 in the first mid-band linear array 70-1. As shown in FIG. 2B, the mid-band radiating elements 72 are mounted on feedboard printed circuit boards 74, with two radiating elements 72 mounted per feedboard printed circuit board 74. The five outputs 40-1 through 40-5 of phase shifter 2 are coupled to the respective five feedboard printed circuit boards 74 via respective coaxial “phase” cables 90. One end of each phase cable 90 is connected to a respective output port 40 of the phase shifter 2 by a pair of solder joints (a first solder joint for the center conductor, the second solder joint for the ground conductor), and the other end of each phase cable 90 is connected to a respective one of the feedboard printed circuit boards 74 by second pair of solder joints. A second phase shifter 2A and a second set of five phase cables 90 (not shown) are included in base station antenna 50 to feed RF signals to the second polarization radiators of the radiating elements in the first mid-band linear array 70-1.

While the conventional base station antenna 50 of FIGS. 2A-2B can support a wide range of communications services, in practice it can be expensive to manufacture. One component of this expense is the large number of solder joints required in the feed network of the antenna. Base station antenna includes four mid-band linear arrays 70 that include ten mid-band radiating elements 72 each for a total of forty mid-band radiating elements. A typical cross-dipole radiating element requires either two or four solder joints to join the feed stalk structure to the dipole radiators. Assuming two solder joints, this means that a total of eighty solder joints are required to form the mid-band radiating elements 72 of base station antenna 50. Four additional solder joints are used to connect each mid-band radiating element 72 to its respective feed board printed circuit board 74, resulting in an additional 160 solder joints. Moreover, each feed board printed circuit board 74 is attached to respective first and second phase shifter printed circuit boards by respective first and second phase cables. Thus eight additional solder joints are required per feed board printed circuit board 74 (four solder joints to connect two phase cables to a respective one of the feedboard printed circuit boards 74, and another four solder joints to connect each phase cable 90 to a respective phase shifter printed circuit board, 10, 10A). Since base station antenna 50 has twenty feed board printed circuit boards 74, an additional 160 solder joints may be required to connect the phase cables 90 between the feedboard printed circuit boards 74 and the phase shifter printed circuit boards 10, 10A. Thus, at least 400 solder joints are required to implement the four mid-band linear arrays 70 and related phase shifters 2, 2A of base station antenna 50.

Even if automated soldering processes are used, forming such a large number of solder joints is still a labor intensive operation, which increases costs. In addition, poorly formed solder joints are a well-known source of passive intermodulation (“PIM”) distortion, which is a type of RF noise that can severely degrade the performance of a base station antenna. Base station antennas are typically tested before they are shipped from the factory to ensure that PIM distortion sources are not present within the antenna. Unfortunately, if a PIM source is identified during testing, it often is difficult to identify the source of the problem, let alone fix the problem, within the assembled antenna since it is difficult to access many of the components of the antenna (and in particular components that are behind the main reflector) due to the crowded design. As a result, when a PIM distortion issue is identified, the base station antenna often must be partly or completely disassembled to identify and fix the problem. This can further increase production costs.

Pursuant to embodiments of the present invention, multi-band base station antennas are provided that may be simpler and less expensive to manufacture than conventional multi-band base station antennas. The base station antennas according to embodiments of the present invention may employ so-called “cableless” or “wireless” phase shifters that include elongated phase shifter printed circuit boards that provide microstrip transmission line connections to the radiating elements (eliminating the need for the above-discussed phase cables), thereby eliminating a large number of solder joints. In addition, the feed stalks of the radiating elements may be part of the phase shifter printed circuit boards, thereby eliminating the need for feedboard printed circuit boards, and eliminating the solder joints that otherwise would be required between the feedboard printed circuit boards and the radiating elements. A base station antenna according to embodiments of the present invention that is the equivalent of conventional base station antenna 50 may, for example, reduce the number of solder joints required to implement the four mid-band linear arrays 70-1 through 70-4 from 400 to 80, which represents an 80% reduction in the number of solder joints. This may reduce manufacturing costs and reduce the extent to which the base station antenna must be reworked to correct identified PIM distortion issues.

As will be discussed in greater detail herein, the phase shifter printed circuit boards included in the base station antennas according to embodiments of the present invention may be much longer than is conventional, and may often extend well over half the length of their associated linear arrays. These longer printed circuit boards are used so that the outputs of the phase shifter may be connected by microstrip transmission lines in the phase shifter printed circuit boards directly to the dipole radiator printed circuit boards (or equivalent structures) of the radiating elements. One disadvantage, however, of connecting the outputs of a phase shifter directly to the radiating elements by microstrip transmission lines is that the insertion loss of RF grade microstrip transmission lines may be higher than the insertion loss of a corresponding length of coaxial cable, and hence the gain of the linear arrays may be reduced if the phase cables are replaced with microstrip transmission lines. In practice, however, phase cable routing issues increase the length of the coaxial cables, and in multiband antennas some of the phase shifters are typically offset from the center of the antenna, which further increases the lengths of the cables. As a result, the additional cable length tends to increase insertion loss, whereas the traces on the printed circuit boards according to embodiments of the present invention may be much straighter. As such, the insertion loss in the feed networks of the antennas according to embodiments of the present invention may in practice be about the same as the insertion loss in a comparable conventional base station antenna.

In some embodiments, the two phase shifter printed circuit boards may be mounted in a stacked arrangement, with the ground planes of the two phase shifter printed circuit boards facing each other. In embodiments where conventional rotary arc phase shifters are used, this arrangement allows a single wiper support to be used that holds the wiper printed circuit boards of the two phase shifters. This arrangement also minimizes the space required behind the reflector to mount the phase shifter printed circuit boards.

As discussed above, the feed stalks for the radiating elements may be formed in the phase shifter printed circuit boards. In particular, each phase shifter printed circuit board may include an elongated first part that extends in the longitudinal direction of the antenna that is mounted behind the reflector of the base station antenna, as well as a plurality of second parts in the form of forwardly-extending tabs that extend through openings in the reflector. Each forwardly-extending tab may form a feed stalk for one of the radiators of the radiating elements, with the tabs on the first polarization phase shifter printed circuit board forming first polarization feed stalks for the respective radiating elements in the array and the tabs on the second polarization phase shifter printed circuit board forming second polarization feed stalks for the respective radiating elements in the array. The first and second polarization feed stalks for each radiating element may be offset from each other in the longitudinal direction of the antenna to reduce coupling between RF signals transmitted through the radiating elements at the two different polarizations.

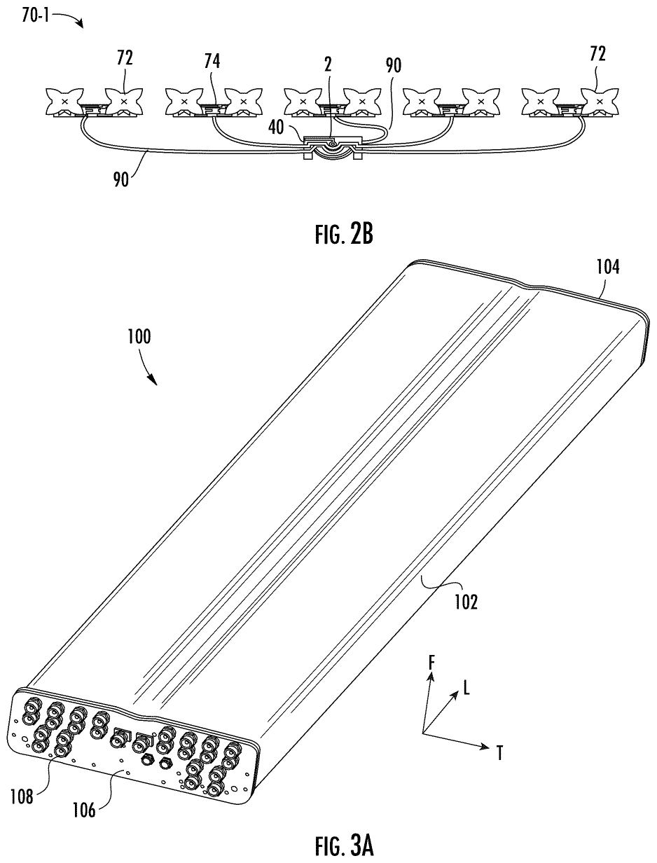

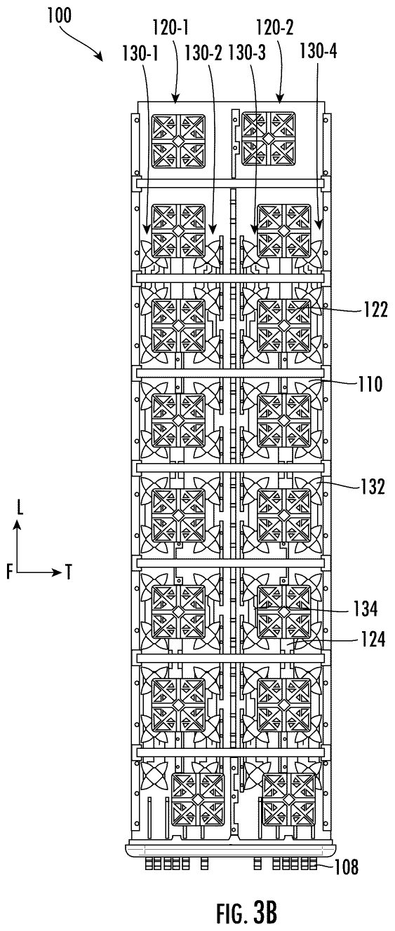

Embodiments of the present invention will now be described in greater detail with reference to FIGS. 3A-8. In the embodiments discussed below, the mid-band linear array assemblies are implemented using phase shifter printed circuit boards that include integrated feed stalks. It will be appreciated, however, that the techniques disclosed herein may be used to form linear array assemblies for radiating elements that operate in other frequency bands. In addition, the techniques disclosed herein may also be used to implement each column of a multi-column beamforming array, where each column may be considered to be a separate linear array

FIGS. 3A-3B illustrate a base station 100 according to embodiments of the present invention. In particular, FIG. 3A is a front perspective view of the base station antenna 100, and FIG. 3B is a schematic front view of base station antenna 100 with the radome removed.

As shown in FIG. 3A, base station antenna 100 has a tubular shape with a generally rectangular cross-section. Base station antenna 100 includes a radome 102, a top end cap 104 and a bottom end cap 106. A plurality of RF ports 108 in the form of RF connectors are mounted in the bottom end cap 106. The RF ports 108 extend through the bottom end cap 106 and are used to electrically connect base station antenna 100 to external radios (not shown). The radome 102, top end cap 104 and bottom cap 106 may form an external housing for the antenna 100. An antenna assembly (FIG. 3B) is contained within this housing.

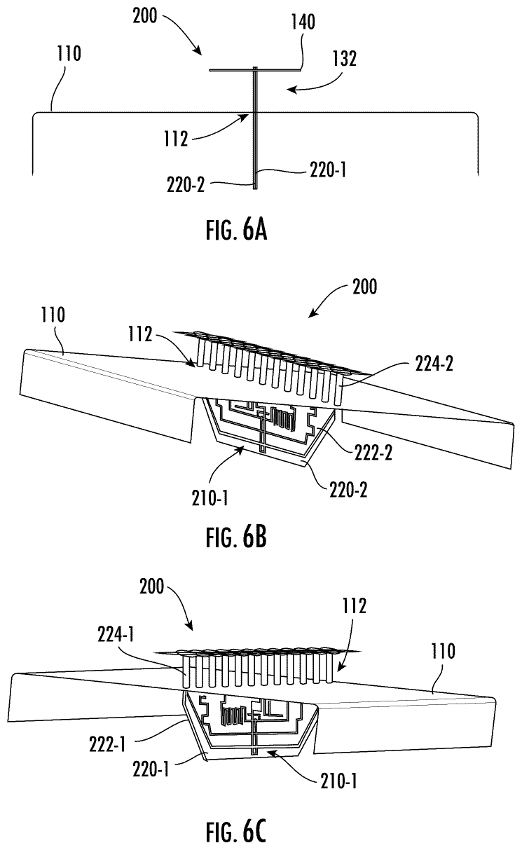

FIG. 3B is a schematic front view of the antenna assembly of base station 100. Base station antenna 100 is similar to base station antenna 50 in many respects. Accordingly, the discussion below will focus on the differences between base station antenna 50 and base station antenna 100. As shown in FIG. 3B, base station antenna 100 includes a reflector 110. The reflector 110 may extend substantially the entire length of the base station antenna 100. The reflector 110 includes a plurality of openings 112 (not visible in FIG. 3B, but see FIGS. 6C-6D). A pair of low-band linear arrays 120-1, 120-2 of low-band radiating elements 122 are mounted forwardly of the reflector 110 with the low-band radiating elements 122 being mounted on feedboard printed circuit boards 124. The low-band arrays 120-1, 120-2 may be identical to the low-band linear arrays 60-1, 60-2 of base station antenna 50, and hence further description thereof will be omitted here.

Base station antenna 100 further includes four mid-band arrays 130-1 through 130-4 of mid-band radiating elements 132 in place of the mid-band arrays 70-1 through 70-4 of base station antenna 50. The mid-band radiating elements 132 are mounted on feedboard printed circuit boards 134. The mid-band radiating elements 72 are dual-polarized radiating elements that each include first and second radiators that are configured to transmit and receive RF energy at orthogonal polarizations. The mid-band radiating elements 72 are configured to transmit and receive signals in the 1427-2690 MHz frequency range or a portion thereof (e.g., the 1695-2690 MHz frequency band). The mid-band arrays 130 serve the same purpose and function as the mid-band arrays 70 of base station antenna 50, but have different feed network and radiating element designs that may significantly reduce the cost and improve the reliability of base station antenna 100 as compared to conventional base station antenna 50. Each mid-band linear array 130 is part of a respective mid-band linear array assembly 200.

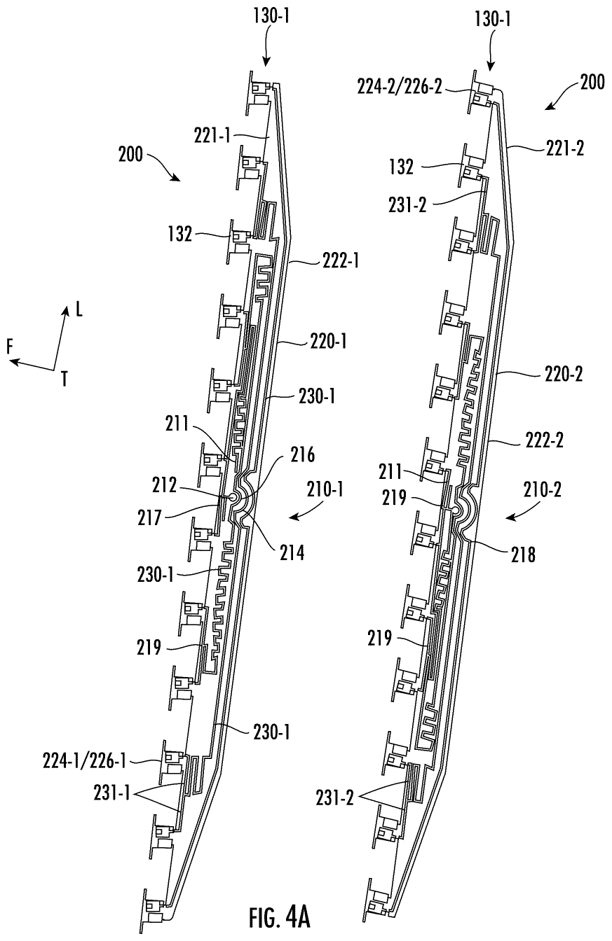

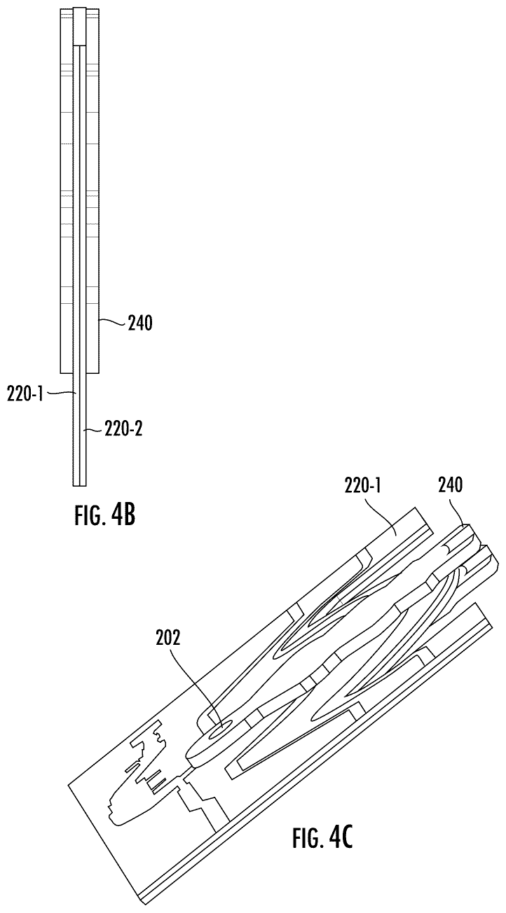

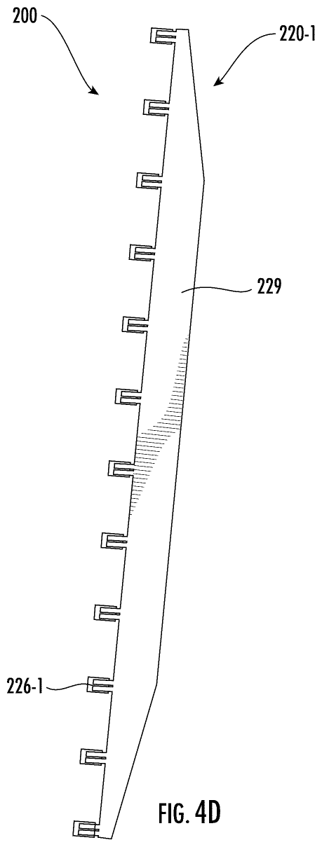

FIG. 4A is a collage that includes right side and left side perspective views of one of the mid-band linear array assemblies 200 of base station antenna 100 of FIGS. 3A-3B. FIG. 4B is an end view of the two main printed circuit boards shown in FIG. 4A with a wiper support mounted thereon. FIG. 4C is an enlarged perspective view of a middle portion of the mid-band linear array assembly 200 shown in FIG. 4B. FIG. 4D is a schematic view of the first main printed circuit board of the linear array assembly of FIG. 4A that illustrates the ground plane formed thereon. The depicted mid-band linear array assembly 200 is the mid-band linear array assembly 200 that includes the first mid-band linear array 130-1. It will be appreciated that base station antenna 100 includes four mid-band linear array assemblies corresponding to the four mid-band linear arrays 130-1 through 130-4. All four of the mid-band linear array assemblies 200 may be identical.

As shown in FIGS. 4A-4D, the mid-band linear array assembly 200 includes the mid-band linear array 130 of mid-band radiating elements 132 as well as two phase shifters 210-1, 210-2. The first phase shifter 210-1 feeds RF signals input at a first of the RF ports 108 (FIGS. 3A-3B) to the first polarization radiators of the mid-band radiating elements 132 in linear array 130-1, and the second phase shifter 210-2 feeds RF signals input at a second of the RF ports 108 (FIGS. 3A-3B) to the second polarization radiators of the mid-band radiating elements 132 in linear array 130-1. The first and second RF ports 108 (FIGS. 3A-3B) may be connected to input ports of the respective first and second phase shifters 210-1, 210-2 by respective first and second coaxial cables (not shown).

The first phase shifter 210-1 includes a first main phase shifter printed circuit board 220-1, a first wiper phase shifter printed circuit board, and a wiper support 240. The first wiper phase shifter printed circuit board is contained within a recess in the wiper support 240 and hence is not visible in the figures. The first wiper phase shifter printed circuit board may be functionally identical to the first wiper phase shifter printed circuit board 20 of conventional phase shifter 2, and hence further description thereof will be omitted here. The wiper support 240 may comprise a piece of plastic that holds the first wiper phase shifter printed circuit board in place facing a first surface of the first main phase shifter printed circuit board 220-1, and may be mounted for rotation relative to the first main phase shifter printed circuit board 220-1 via a pivot pin 202 (FIG. 4C).

The first main phase shifter printed circuit board 220-1 includes a first dielectric substrate 221-1 with metallization thereon. In particular, a plurality of metal traces and input and output pads may be formed on a first side of the first dielectric substrate 221-1. These traces and pads include an input pad 211, which acts as the input port of the first phase shifter 210-1, a fixed delay trace 217, three arcuate traces 212, 214, 216, and seven output pads 218. The input pad 211 may comprise a first end of the fixed delay trace 217 and the output pads may comprise the second end of the fixed delay trace 217 and the two ends of the three arcuate traces 212, 214, 216 (thereby providing seven output pads 218). As shown in FIG. 4D, a ground plane 229 may be formed on the second (opposed) side of the first dielectric substrate 221-1 so that the traces 212, 214, 216, 217 will operate as microstrip transmission lines.

The first phase shifter 210-1 may be an arc rotary phase shifter that is structurally very similar and functionally identical to the phase shifter 2 described above with reference to FIG. 1. The first phase shifter 210-1 differs from phase shifter 2, however, in that (1) the first main phase shifter printed circuit board 220-1 includes three arcuate traces 212, 214, 216 (instead of the two arcuate traces 12, 14 in phase shifter 2) and hence has a total of seven outputs 218 (instead of the five outputs 40-1 through 40-5 in phase shifter 2) and (2) the first main phase shifter printed circuit board 220-1 is greatly elongated in the longitudinal direction L as compared to the first main phase shifter printed circuit board 10 of phase shifter 2, and (3) seven first microstrip transmission lines 230-1 are connected to the seven outputs 218 of the phase shifter 210-1 (namely to the ends of the arcuate traces 212, 214, 216 and to the end of a fixed phase shift trace 217) and (4) five power dividers 219 are provided that split five of the microstrip transmission lines 230-1 into pairs of first microstrip transmission lines 231-1. As will be discussed in greater detail below, the first microstrip transmission lines 230-1, 231-1 and the power dividers 219 may be used to directly feed the first polarization radiators of the radiating elements 132 in the first mid-band linear array 130-1 from the seven outputs 218 of the phase shifter 210-1.

Still referring to FIG. 4A, it can be seen that the first main phase shifter printed circuit board 220-1 includes an elongated first (or “main”) part 222-1 that has a rectangular shape with the two rear corners of the rectangle heavily-beveled, and a plurality of second parts 224-1 in the form of generally rectangular tabs that extend in the forward direction from the main part 222-1. As shown in FIG. 6C, the main part 222-1 of first main phase shifter printed circuit board 220-1 may be positioned behind the reflector 110 of base station antenna 100 and the tabs 224-1 of first main phase shifter printed circuit board 220-1 may extend through respective openings 112 (e.g., slots) in the reflector 110 so that the tabs 224-1 extend forwardly of the reflector 110. The main part 222-1 may comprise the main printed circuit board 220-1 of first phase shifter 210-1, and the first microstrip transmission lines 230-1 on the main printed circuit board 220-1 may replace the phase cables 90 that are included in the conventional base station antenna 50 (see FIG. 2B above).

Referring again to FIG. 4A, each tab 224-1 of the first main phase shifter printed circuit board 220-1 may comprise a first polarization feed stalk 226-1 of a respective one of the radiating elements 132 in the linear array 130-1. The first microstrip transmission lines 230-1, 231-1 extend onto the first polarization feed stalks 226-1 so that an end portion of each first microstrip transmission line 230-1, 231-1 may serve as the signal trace on a respective one of the first polarization feed stalks 226-1.

Thus, as shown in FIG. 4A, the first microstrip transmission lines 230-1, 231-1 implement a plurality of continuous microstrip transmission lines that extend from the outputs 218 of the phase shifter 210-1 onto the first polarization feed stalks 226-1 where these transmission lines feed the first polarization dipole radiators of the radiating elements 132 in linear array 130-1. These continuous microstrip transmission lines directly connect to the microstrip transmission lines of the first phase shifter 210-1 (i.e., the arcuate traces 212, 214, 216 and the fixed delay trace 217) so that continuous RF transmission lines are provided that are free of solder joints all of the way from the input of the first phase shifter 210-1 to the first polarization feed stalks 226-1. As such, the only solder joints provided are the solder joints connecting the first polarization feed stalks 226-1 to the dipole radiators of the radiating elements 132.

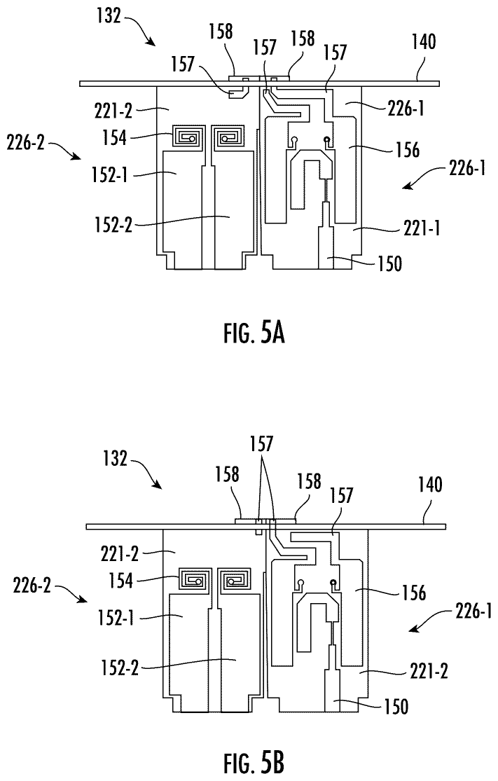

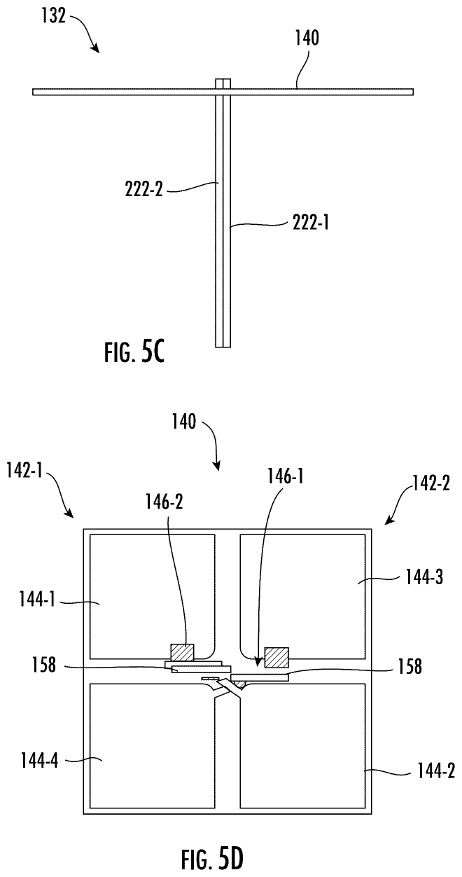

As best shown in FIGS. 4A and 4B, the second phase shifter 210-2 includes a second main phase shifter printed circuit board 220-2, a second wiper phase shifter printed circuit board (not visible in the figures) and the wiper support 240. The second phase shifter 210-2 may be essentially identical to the first phase shifter 210-1, except that (1) the tabs 224-2 of the second main phase shifter printed circuit board 220-2 act as the second polarization feed stalks 226-2 for the second polarization dipole radiators of the radiating elements 132 in linear array 130-1 and (2) the tabs 224-2 are offset from the tabs 224-1 in the longitudinal direction L. The dipole radiators of each radiating element 132 are mounted on the first and second polarization feed stalks 226-1, 226-2, as will be discussed in greater detail with reference to FIGS. 5A-5D.

As shown in FIGS. 4B and 4C, the wiper support 240 holds the first wiper phase shifter printed circuit board against the first main phase shifter printed circuit board 220-1 so that the first wiper phase shifter printed circuit board may rotate relative to the first main phase shifter printed circuit board 220-1 and so that sub-components of RF signals that are input to the first main phase shifter printed circuit board 220-1 may capacitively couple between the first main phase shifter printed circuit board 220-1 and the first wiper phase shifter printed circuit board. Similarly, the wiper support 240 holds the second wiper phase shifter printed circuit board against the second main phase shifter printed circuit board 220-2 so that the second wiper phase shifter printed circuit board may rotate relative to the second main phase shifter printed circuit board 220-2 and so that sub-components of RF signals that are input to the second main phase shifter printed circuit board 220-2 may capacitively couple between the second main phase shifter printed circuit board 220-2 and the second wiper phase shifter printed circuit board.

As discussed above, at least 400 solder joints are used to implement the mid-band linear arrays 70 of conventional base station antenna 50. The conventional base station antenna 50 includes four mid-band linear arrays 70-1 through 70-4 that each have ten mid-band radiating elements 72 and five feedboard printed circuit boards 74, whereas base station antenna 100 includes four mid-band linear arrays 130-1 through 130-4 that each have twelve mid-band radiating elements 132 and seven feedboard printed circuit boards 134. If conventional base station antenna 50 was modified to have four mid-band linear arrays that had twelve radiating elements 72 per array that are mounted on seven feedboard printed circuit boards 74 per array and coupled to seven-output phase shifters - which would be equivalent to the mid-band linear array assemblies 200 of base station antenna 100 - the total number of solder joints required to implement the mid-band linear arrays would increase to 512 solder joints.

As shown in FIG. 4A, the microstrip transmission lines 230-1, 231-1 extend from the outputs 218 of the first phase shifter 210-1 onto the first polarization feed stalks 226-1 and the microstrip transmission lines 230-2, 231-2 extend from the outputs 218 of the second phase shifter 210-2 onto the second polarization feed stalks 226-2. As such, the phase cables 90 and the feedboard printed circuit boards 74 that are present in base station antenna 50 are omitted in base station antenna 100. Accordingly, the solder joints that are present in base station antenna 50 that connect the feedboard printed circuit boards 74 to the feed stalks of the radiating elements 72 are omitted in base station antenna 100, as are the solder joints that are present in base station antenna 50 that connect the feedboard printed circuit boards 74 to the phase cables 90 and the solder joints that connect the phase cables 90 to the first and second phase shifters 2, 2A. In fact, the only solder joints included on the electrical paths from the phase shifters 210-1, 210-2 to the radiating elements 132 in base station antenna 100 are the first and second solder joints connecting the first and second polarization feed stalks 226-1, 226-2 to the dipole radiators. Thus, implementing the mid-band linear array assemblies 200 of base station antenna 100 only requires 96 solder joints, whereas a comparable conventional base station antenna would require 512 solder joints.

As described above, solder joints are labor intensive operations, and hence the reduction in solder joints that is possible in base station antenna 100 can significantly reduce the cost of manufacturing base station antenna 100 as compared to base station antenna 50. Replacing the coaxial cables and feedboard printed circuit boards with the larger main phase shifter printed circuit boards as disclosed herein also helps reduce the cost of the antenna. In addition, eliminating 80% or more of the solder joints can dramatically reduce the amount of rework activity required to identify PIM distortion sources uncovered during post-manufacture testing, since poorly-formed solder joints are a significant source of PIM distortion.

Replacing the phase cables of base station antenna 50 with microstrip transmission lines 230, 231 in base station antenna 100 does have the potential to increase the insertion loss of base station antenna 100 as compared to base station antenna 50, since the insertion loss of microstrip transmission lines implemented on RF-quality printed circuit boards is nearly twice that of a typical coaxial phase cable. However, in practice each phase cable 90 may be nearly twice as long as would otherwise be necessary because the phase cables 90 are routed around other structures in the antenna 50 which increases the length thereof, and slack is also provided in the phase cables 90 to make soldering rework operations easier. In contrast, the microstrip transmission lines 230, 231 are not routed around other structures in base station antenna 100 and do not require slack. Thus, the length of the microstrip transmission lines 230, 231 in base station antenna 100 may only be about 60% of the length of the corresponding coaxial phase cables 90 in base station antenna 50. As such, the insertion loss in the feed networks of the antennas according to embodiments of the present invention may in practice be about the same as the insertion loss in a comparable conventional base station antenna.

FIG. 4D is a schematic view of the opposite side of the first main printed circuit board 210-1 of the linear array assembly 200 of FIG. 4A. As shown in FIG. 4D, the second side of the dielectric substrate 221-1 may be substantially covered by a metal ground plane 229 so that the traces (e.g., traces 212, 214, 216, 217 and the traces of the microstrip transmission lines 230, 231) on the first side of the dielectric substrate 221-1 operate as microstrip transmission lines. The metallization forming the ground plane extends onto the first polarization feed stalks 226-1 to form a pair of ground lines on each first polarization feed stalk 226-1, as will be discussed in greater detail below with reference to FIGS. 5A-5C. The opposite side of the second main printed circuit board 210-2 of the linear array assembly 200 may be substantially identical to what is shown in FIG. 4A, having a metal ground plane 229 that extends onto the second polarization feed stalks 226-2.

FIGS. 5A-5D illustrate one of the mid-band radiating elements 132 according to embodiments of the present invention in greater detail. In particular, FIGS. 5A and 5B are right side and left side views of one of the radiating elements 132 included in one of the mid-band linear arrays 130 of FIG. 3B. FIG. 5C is a top view of the radiating element 132, and FIG. 5D is a plan view of a dipole radiator printed circuit board of the radiating element 132.

As shown in FIGS. 5A-5D, the mid-band radiating element 132 includes a first polarization feed stalk printed circuit board 226-1, a second polarization feed stalk printed circuit board 226-2, and a dipole radiator printed circuit board 140. The first polarization feed stalk printed circuit board 226-1 and the second polarization feed stalk printed circuit board 226-2 may be substantially identical to each other, except that they face in opposed directions. As shown, the first polarization feed stalk printed circuit board 226-1 comprises a portion of the first main phase shifter printed circuit board 220-1, and hence includes a portion of the first dielectric substrate 221-1. A signal trace 150 is formed on a first major surface of the dielectric substrate 221-1 and a pair of ground lines 152-1, 152-2 are formed on an opposed second major surface of the dielectric substrate 222-1. The signal trace 150 has a hook shape. The signal trace 150 overlaps the first and second ground lines 152-1, 152-2 to form an RF transmission line.

One problem that may arise when radiating elements that operate in different frequency bands are positioned in close proximity to each other in a base station antenna is that a higher frequency radiating element may have a so-called “common mode resonance” that can distort the antenna beam of a nearby lower-band radiating element. Dipole-based radiating elements such as mid-band radiating elements 132 are differentially fed devices. However, the combination of the feed stalk and the dipole arm may resonate as a quarter wavelength monopole radiator. In other words, if RF radiation impinges on the mid-band radiating element 132 at a frequency that has a corresponding wavelength that is about four times the electrical length of the combination of the feed stalk and a dipole arm, then common mode currents may form on the feed stalk and the dipole radiator. These common mode currents will also cause radiation of RF energy. Typically, both the feed stalk and the dipole arms of a dipole-based radiating element have a length that is about one-quarter a wavelength (called the “center wavelength” herein) corresponding the center frequency of the operating frequency band of the radiating element. Thus, the combined length of the feed stalk and the dipole arm is about one-half the center wavelength. Since much of the mid-band operating frequency range includes frequencies that are twice the frequency of frequencies within the low-band operating frequency range, the combined length of the feed stalk and the dipole arm of a typical mid-band radiating element will be a little less than one quarter of the center wavelength of the low-band operating frequency range. As a result, common mode currents may flow on the mid-band radiating elements 132 of base station antenna 100 in response to RF energy that is transmitted by nearby low-band radiating elements 122. As these common mode currents emit RF radiation, the net effect is that the mid-band radiating elements 132 may distort the antenna beams of nearby low-band radiating elements 122, degrading the performance of the low-band arrays 120. For example, the low-band radiation patterns may have reduced directivity and higher beamwidths than desired.

As shown in FIGS. 5A-5B, the first and second polarization feed stalk printed circuit boards 226-1, 226-2 each include integrated inductor-capacitor (“LC”) circuits along the current path to the dipole radiators of the mid-band radiating element 132. In particular, an inductor 154 is coupled to the upper end (forward end when the radiating element 132 is mounted for normal use) of each ground line 152, and plates 156 are formed on the signal trace 150 side of the dielectric substrates 221 that capacitively couple with the respective ground lines 152. These LC circuits are configured to move common mode resonances that otherwise could be induced on the mid-band radiating element 132 in response to RF energy emitted by nearby low-band radiating elements so that the resonance is outside the operating frequency range of the low-band radiating elements 122.

Each first and second polarization feed stalk printed circuit board 226-1, 226-2 includes a forwardly-extending projection 158. Additionally, the plates 156 have metallized extensions 157 that extend onto the projections 158. The metallized extensions 157 can be physically and electrically connected to the dipole radiators of the radiating elements 132 via solder joints.

Each radiating element 132 further includes a dipole radiator printed circuit board 140. The dipole radiator printed circuit board 140 may be of conventional design. For example, as shown in FIG. 5D, the dipole radiator printed circuit board 140 includes a first polarization dipole radiator 142-1 that includes first and second center-fed dipole arms 144-1, 144-2, and a second polarization dipole radiator 142-2 that includes third and fourth center-fed dipole arms 144-3, 144-4. The dipole radiator printed circuit board 140 further includes at least one slot 146. In the depicted embodiment, the dipole radiator printed circuit board 140 includes first and second slots 146-1, 146-2 that receive the respective forwardly-extending projections 158 of the first and second polarization feed stalk printed circuit board 226-1, 226-2 so that the dipole radiator printed circuit board 140 is mounted on the first and second polarization feed stalk printed circuit board 226-1, 226-2. In other embodiments, a single slot 146 may receive both forwardly-extending projections 158 of the first and second polarization feed stalk printed circuit board 226-1, 226-2.

While FIG. 5D illustrates implementing the dipole radiators in a dipole radiator printed circuit board, it will be appreciated that other implementations are possible. For example, sheet metal dipole arms may be used in other embodiments, or the combination of a small coupling printed circuit board and sheet metal dipole arms.

FIG. 6A is a top view one of the mid-band linear array assemblies 200 of the base station antenna 100 of FIGS. 3A-3B FIGS. 6B and 6C are schematic left and right side views of the linear array assembly of FIG. 6A mounted on the reflector 110 of the base station antenna 100.

As shown in FIGS. 6A-6C, the mid-band linear array assembly 200 includes portions on both sides of the reflector 110. In particular, the first parts 222-1, 222-2 of the main phase shifter printed circuit boards 220-1, 220-2 are mounted behind the reflector 110, while the second parts 224-1, 224-2 of the main phase shifter printed circuit boards 220-1, 220-2 that form the first and second polarization feedboard printed circuit boards 226-1, 226-2 extend through openings 112 in the reflector 110 so that the first and second polarization feedboard printed circuit boards 226-1, 226-2 are in front of the reflector 110.

Referring again to FIGS. 3A-6C, pursuant to some embodiments of the present invention, base station antennas such as base station antenna 100 are provided that comprise a reflector 110, a first RF port 108, a first array 130-1 of radiating elements 132 that extends in a longitudinal direction L, and a first printed circuit board 220-1 that comprises a first dielectric substrate 221-1 and a plurality of first metal traces 212, 214, 216, 217 on a first major surface of the first dielectric substrate 221-1, the first metal traces 212, 214, 216, 217 implementing a portion of a first phase shifter 210-1. The first printed circuit board 220-1 comprises a main part 222-1 that is mounted behind the reflector 110 and a plurality of tabs 224-1 that extend forwardly through one or more first openings 112 in the reflector 110.

The tabs 224-1 of the first printed circuit board 220-1 may comprise a plurality of first polarization feed stalks 226-1 for respective ones of at least some of the radiating elements 132 in the first array 130 of radiating elements. In the depicted embodiment, the first printed circuit board 220-1 has twelve forwardly-extending tabs 224-1 so that all of the first polarization feed stalks 226-1 are implemented as part of the first printed circuit board 220-1. As will be discussed below, in other embodiments, the first printed circuit board 220-1 may include fewer tabs 224-1 so that only a subset of the first polarization feed stalks 226-1 are implemented using tabs 224-1. For example, the first polarization feed stalks 226-1 of at least four, five, six, eight, ten or more of the radiating elements 132 may be implemented via forwardly-extending tabs 224-1 on the first printed circuit board 220-1.

The first RF port 108 is coupled to an input of the first phase shifter 210-1 and a first of a plurality of outputs 218 of the first phase shifter 210-1 is coupled to a first signal trace 150-1 that is on a first of the first polarization feed stalks 226-1 and a second of the plurality of outputs 218 of the first phase shifter 210-1 is coupled to a second signal trace 150-1 that is on a second of the first polarization feed stalks 226-1.

Base station antenna 100 further comprises a second RF port 108, a second printed circuit board 220-2 that comprises a second dielectric substrate 221-2 and a plurality of second metal traces 212, 214, 216, 217 on a first major surface of the second dielectric substrate 221-2, the second metal traces 212, 214, 216, 217 implementing a portion of a second phase shifter 210-2. The second printed circuit board 220-2 comprises a main part 222-2 that is mounted behind the reflector 110 and a plurality of tabs 224-2 that extend forwardly through one or more second openings 112 in the reflector 110. The tabs 224-2 form the second polarization feed stalks 226-2 for the respective radiating elements 132 in the first array 130-1 of radiating elements 132. Each radiating element 132 in the first array 130 of radiating elements 132 thus comprises a feed stalk structure that includes a respective one of the first polarization feed stalks 226-1 and a respective one of the second polarization feed stalks 226-2.

In some embodiments, a length of the first printed circuit board 210-1 in the longitudinal direction L may be at least 50%, at least 60%, at least 70% or at least 80% a length of the first array 130-1 in the longitudinal direction.

The second RF port 108 is coupled to an input of the second phase shifter 210-2 and a first of a plurality of outputs 218 of the second phase shifter 210-2 is coupled to a signal trace that is on a first of the second polarization feed stalks 226-2 and a second of the plurality of outputs 218 of the second phase shifter 210-2 is coupled to a signal trace that is on a second of the second polarization feed stalks 226-2.

As shown best in FIG. 4A, centers of the first and second polarization feed stalks 226-1, 226-2 that form each feed stalk structure are offset in the longitudinal direction l. As such, metallization of the first and second polarization feed stalks 226-1, 226-2 of a first of the radiating elements 132 do not overlap in a transverse direction T that is perpendicular to the longitudinal direction L and to a forward direction F of base station antenna 100.

Each radiating element 132 includes a respective dipole radiator printed circuit board 140 that includes a first slot 146-1 that receives the forwardly-extending tab 158 of a respective one of the first polarization feed stalks 226-1 and a second slot 146-2 that receives the forwardly-extending tab 158 of a respective one of the second polarization feed stalks 226-2.

A first ground plane 229 is provided on a second major surface of the first dielectric substrate 221-1 and a second ground plane 229 is provided on a second major surface of the second dielectric substrate 221-2. The first printed circuit board 220-1 and the second printed circuit board 220-2 are mounted back-to-back with the first ground plane 229 facing the second ground plane 229. A solder mask (not visible in the figures) is interposed between the first ground plane 229 and the second ground plane 229.

The first printed circuit board 220-1 and the reflector 110 both have longitudinal axes that extend in the longitudinal direction L, with the first printed circuit board 220-1 defining a first plane and the reflector 110 defining a second plane that is perpendicular to the first plane.

Still referring to FIGS. 3A-6C, pursuant to further embodiments of the present invention, base station antennas such as base station antenna 100 are provided that comprise a reflector 110 that has a top end and a bottom end that are separated from each other in a longitudinal direction L of the base station antenna 100 and a first side and a second side that are separated from each other in a transverse direction that is perpendicular to the longitudinal direction. Base station antenna 100 further includes a first dual-polarized radiating element 132 that has first and second dipole radiators 142-1, 142-2 that are positioned forwardly of the reflector 110, where the first dual-polarized radiating element 132 comprises a first polarization feed stalk 226-1 and a second polarization feed stalk 226-2. The first polarization feed stalk 226-1 has a first dielectric substrate 221-1 and the second polarization feed stalk 226-2 has a second dielectric substrate 221-2. Each of the first and second dielectric substrates 221-1, 221-2 has a first major surface and a second major surface. The first polarization feed stalk 226-1 and the second polarization feed stalk 226-2 have respective first and second longitudinal axes that extend in a forward direction F that is perpendicular to both the longitudinal direction L and the transverse direction T. The first major surface of the first dielectric substrate 221-1 extends in parallel to the first major surface of the second dielectric substrate 221-2, and metallization on the first dielectric substrate 221-1 does not overlap metallization on the second dielectric substrate 221-2 in the transverse direction T. The first radiating element 132 further includes a dipole radiator printed circuit board 140 that is mounted on the first and second polarization feed stalks 226-1, 226-2.

Microstrip transmission lines 230-1, 231-1 are provided on the first major surface of the first dielectric substrate 221-1, a first ground plane 229 is provided on the second major surface of the first dielectric substrate 221-1, microstrip transmission lines 230-2, 231-2 are provided on the first major surface of the second dielectric substrate 221-2, and a second ground plane 229 is provided on the second major surface of the second dielectric substrate 221-2. The first polarization feed stalk 226-1 is part of a first printed circuit board 220-1 that includes first metal traces 212, 214, 216, 217 that implement a portion of a first phase shifter 210-1, and the second polarization feed stalk 226-2 is part of a second printed circuit board 220-2 that includes second metal traces 212, 214, 216, 217 that implement a portion of a second phase shifter 210-2. The first polarization feed stalk 226-1 and the second polarization feed stalk 226-2 do not overlap in the transverse direction T. An output 218 of the first phase shifter 210-1 is directly connected to a signal trace 150 on the first polarization feed stalk 226-1 via a microstrip transmission line 230-1, 231-1. The first polarization feed stalk 226-1 extends through an opening 112 in the reflector 110. A distal end of the first polarization feed stalk 226-1 is positioned forwardly of the reflector 110 and the first metal traces 212, 214, 216, 217 that implement a portion of the first phase shifter 226-1 are positioned rearwardly of the reflector 110.

According to still further embodiments of the present invention, base station antennas such as base station antenna 100 are provided that comprise a reflector 110, a first array 130-1 of radiating elements 132 that extends in a longitudinal direction L, where each of the radiating elements 132 in the first array 130-1 includes a respective pair of dipole radiators 142-1, 142-2 and a respective feed stalk structure that mounts the pair of dipole radiators 142-1, 142-2 forwardly of the reflector 110. The base station antenna 100 further includes a first printed circuit board 220-1 that comprises a first part 222-1 that is mounted behind the reflector 110 and a plurality of second parts 224-1 that extend forwardly through one or more first openings 112 in the reflector 110. A first of the second parts 224-1 forms part of the feed stalk structure for a first of the radiating elements 132 and a second of the second parts 224-2 forms part of the feed stalk structure for a second of the radiating elements 132.

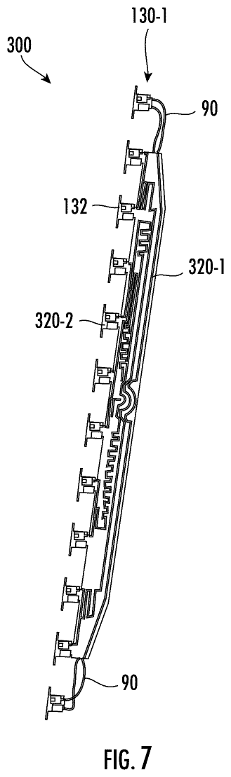

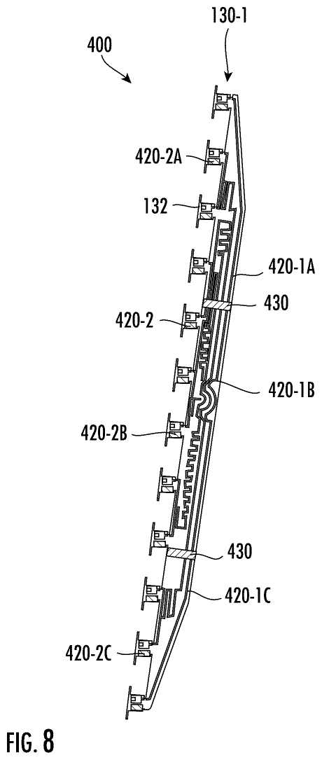

FIG. 7 is a schematic perspective view of an alternative mid-band linear array assembly 300 according to further embodiments of the present invention that uses shorter first and second main printed circuit boards 320-1, 320-2 and connects the outer radiating elements 132 in the mid-band linear array 130-1 to the main printed circuit boards 320-1, 320-2 using phase cables 90. In some cases, it may not be possible to obtain printed circuit boards that are long enough the directly feed all of the radiating elements in an array, or the cost of the printed circuit boards may be too high. In such cases, somewhat shorter first and second main printed circuit boards 320-1, 320-2 may be used in place of the first and second main printed circuit boards 220-1, 220-2 included in base station antenna 100. In the example embodiment shown in FIG. 7, the shorter first and second main printed circuit boards 320-1, 320-2 feed the ten mid-band radiating elements that form the middle portion of the linear array 130-1. The radiating elements 132 that are at the top and bottom of the linear array 130-1 are each fed by a pair of phase cables 90, with the first phase cable 90 connecting a microstrip transmission line on the first main printed circuit board 320-1 to a first polarization feed stalk of the radiating element 132, and the second phase cable 90 connecting a microstrip transmission line on the second main printed circuit board 320-2 to a second polarization feed stalk of the radiating element 132. Note that the radiating elements 132 that are at the top and bottom of the linear array 130-1 each have separate first and second polarization feed stalks that are not part of the respective first and second main printed circuit boards 320-1, 320-2.

Thus, as shown in FIG. 7, an end radiating element 132 in the first array 130-1 of radiating elements 132 that is at either end of the array is electrically connected to the first printed circuit board 320-1 through a cable 90.

FIG. 8 is a schematic perspective view of another alternative mid-band linear array assembly 400 according to embodiments of the present invention that replaces each main printed circuit board 220 of the mid-band linear array assembly 200 of FIG. 4A with three shorter main printed circuit boards that are interconnected to each other using jumper printed circuit boards. As shown in FIG. 8, the mid-band linear array assembly 400 includes a set of three first main printed circuit boards 420-1A, 420-1B, 420-1C and a set of three second main printed circuit boards 420-2A, 420-2B, 420-2C. The mid-band linear array assembly 400 further includes four jumper printed circuit boards 430, only two of which are visible in the view of FIG. 8. Each jumper printed circuit board 430 is mounted two of the main printed circuit boards 420-1A, 420-1B, 420-1C, 420-2A, 420-2B, 420-2C and used to join the two main printed circuit boards 420-1A, 420-1B, 420-1C, 420-2A, 420-2B, 420-2C together and to electrically connect microstrip transmission lines that are on the two main printed circuit boards 420-1A, 420-1B, 420-1C, 420-2A, 420-2B, 420-2C. In this manner, multiple smaller main printed circuit boards may be used in place of each of the larger main printed circuit boards 220-1, 220-1 of mid-band linear array assembly 200. As all other aspects of mid-band linear array assembly 400 may be the same as mid-band linear array assembly 200, further description thereof will be omitted here.

The present invention has been described above with reference to the accompanying drawings. The present invention is not limited to the illustrated embodiments. Rather, these embodiments are intended to fully and completely disclose the present invention to those skilled in this art. In the drawings, like numbers refer to like elements throughout. Thicknesses and dimensions of some components may be exaggerated for clarity.

Spatially relative terms, such as “under,” “below,” “lower,” “over,” “upper,” “top,” “bottom,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the example term “under” can encompass both an orientation of over and under. The device may be otherwise oriented (rotated 90 degrees or at other orientations) and the spatially relative descriptors used herein interpreted accordingly.

Herein, the terms “attached,” “connected,” “interconnected,” “contacting,” “mounted,” “coupled,” and the like can mean either direct or indirect attachment or coupling between elements, unless stated otherwise.

Well-known functions or constructions may not be described in detail for brevity and/or clarity. As used herein the expression “and/or” includes any and all combinations of one or more of the associated listed items.

The terminology used herein is for the purpose of describing particular embodiments only and is not intended to be limiting of the present invention. As used herein, the singular forms “a,” “an,” and “the” are intended to include the plural forms as well, unless the context clearly indicates otherwise. It will be further understood that the terms “comprises,” “comprising,” “includes,” and/or “including” when used in this specification, specify the presence of stated features, operations, elements, and/or components, but do not preclude the presence or addition of one or more other features, operations, elements, components, and/or groups thereof.

1. A base station antenna, comprising:
a reflector;
a first radio frequency (“RF”) port;
a first array of radiating elements that extends in a longitudinal direction;
a first printed circuit board that comprises a first dielectric substrate and a plurality of first metal traces on a first major surface of the first dielectric substrate, the first metal traces implementing a portion of a first phase shifter, the first printed circuit board comprising a first part that is mounted behind the reflector and a plurality of second parts that extend forwardly through one or more first openings in the reflector.

2. The base station antenna of claim 1, wherein the plurality of second parts comprise a plurality of first polarization feed stalks for respective ones of at least four of the radiating elements in the first array of radiating elements.

3. The base station antenna of claim 2, wherein the first RF port is coupled to an input of the first phase shifter and a first of a plurality of outputs of the first phase shifter is coupled to a first signal trace that is on a first of the first polarization feed stalks and a second of the plurality of outputs of the first phase shifter is coupled to a second signal trace that is on a second of the first polarization feed stalks.

4. The base station antenna of claim 3, further comprising:
a second RF port;
a second printed circuit board that comprises a second dielectric substrate and a plurality of second metal traces on a first major surface of the second dielectric substrate, the second metal traces implementing a portion of a second phase shifter, the second printed circuit board comprising a third part that is mounted behind the reflector and a plurality of fourth parts that extend forwardly through one or more second openings in the reflector.

5. The base station antenna of claim 4, wherein the first dielectric substrate has a second major surface with a metal ground plane thereon.

6. (canceled)

7. The base station antenna of claim 4, wherein the plurality of fourth parts comprise a plurality of second polarization feed stalks for the respective radiating elements in the first array of radiating elements.

8. (canceled)

9. The base station antenna of claim 7, wherein each radiating element in the first array of radiating elements comprises a feed stalk structure that includes a respective one of the first polarization feed stalks and a respective one of the second polarization feed stalks.

10. The base station antenna of claim 7, wherein centers of the first and second polarization feed stalks that form each feed stalk structure are offset in the longitudinal direction.

11. (canceled)

12. The base station antenna of claim 7, wherein each radiating element further comprises a respective dipole radiator printed circuit board that includes a first slot that receives a forward end of a respective one of the first polarization feed stalks and a second slot that receives a forward end of a respective one of the second polarization feed stalks.

13. The base station antenna of claim 4, wherein a first ground plane is provided on a second major surface of the first dielectric substrate and a second ground plane is provided on a second major surface of the second dielectric substrate.

14-18. (canceled)

19. A base station antenna, comprising:
a reflector that has a top end and a bottom end that are separated from each other in a longitudinal direction of the base station antenna and a first side and a second side that are separated from each other in a transverse direction that is perpendicular to the longitudinal direction; and
a first dual-polarized radiating element that has first and second dipole radiators that are positioned forwardly of the reflector, the first dual-polarized radiating element comprising:
a first polarization feed stalk that has a first dielectric substrate that has a first major surface and a second major surface, the first polarization feed stalk having a first longitudinal axis that extends in a forward direction that is perpendicular to both the longitudinal direction and the transverse direction;
a second polarization feed stalk that has a second dielectric substrate that has a first major surface and a second major surface, the second polarization feed stalk having a second longitudinal axis that extends in the forward direction,
wherein the first major surface of the first dielectric substrate extends in parallel to the first major surface of the second dielectric substrate, and
wherein metallization on the first dielectric substrate does not overlap metallization on the second dielectric substrate in the transverse direction.

20-21. (canceled)

22. The base station antenna of claim 19, wherein first microstrip transmission lines are provided on the first major surface of the first dielectric substrate, a first ground plane is provided on the second major surface of the first dielectric substrate, second microstrip transmission lines are provided on the first major surface of the second dielectric substrate, and a second ground plane is provided on the second major surface of the second dielectric substrate.

23. The base station antenna of claim 22, wherein the first polarization feed stalk is part of a first printed circuit board that includes first metal traces that implement a portion of a first phase shifter, and the second polarization feed stalk is part of a second printed circuit board that includes second metal traces that implement a portion of a second phase shifter.

24. The base station antenna of claim 23, wherein a distal end of the first polarization feed stalk is positioned forwardly of the reflector and the first metal traces that implement the portion of the first phase shifter are positioned rearwardly of the reflector.

25-27. (canceled)

28. The base station antenna of claim 23, wherein an output of the first phase shifter is directly connected to a signal trace on the first polarization feed stalk via a microstrip transmission line.

29. A base station antenna, comprising:
a reflector that has a top end and a bottom end that are separated from each other in a longitudinal direction of the base station antenna and a first side and a second side that are separated from each other in a transverse direction that is perpendicular to the longitudinal direction; and
a first dual-polarized radiating element that has first and second dipole radiators that are positioned forwardly of the reflector, the first dual-polarized radiating element comprising:
a first polarization feed stalk that has a first dielectric substrate that has a first major surface and a second major surface, the first polarization feed stalk having a first longitudinal axis that extends in a forward direction that is perpendicular to both the longitudinal direction and the transverse direction;
a second polarization feed stalk that has a second dielectric substrate that has a first major surface and a second major surface, the second polarization feed stalk having a second longitudinal axis that extends in the forward direction; and
a dipole radiator printed circuit board mounted on the first polarization feed stalk and the second polarization feed stalk,
wherein the first major surface of the first dielectric substrate extends in parallel to the first major surface of the second dielectric substrate.

30. (canceled)

31. The base station antenna of claim 29, wherein the first polarization feed stalk comprises a first tab that extends through the dipole radiator printed circuit board and the second polarization feed stalk comprises a second tab that extends through the dipole radiator printed circuit board, where a center of the first tab is offset from a center of the second tab in the longitudinal direction.

32. The base station antenna of claim 29, wherein first microstrip transmission lines are provided on the first major surface of the first dielectric substrate, a first ground plane is provided on the second major surface of the first dielectric substrate, second microstrip transmission lines are provided on the first major surface of the second dielectric substrate, and a second ground plane is provided on the second major surface of the second dielectric substrate.

33. The base station antenna of claim 32, wherein the first polarization feed stalk is part of a first printed circuit board that includes first metal traces that implement a portion of a first phase shifter, and the second polarization feed stalk is part of a second printed circuit board that includes second metal traces that implement a portion of a second phase shifter.

34. The base station antenna of claim 33, wherein a distal end of the first polarization feed stalk is positioned forwardly of the reflector and the first metal traces that implement the portion of the first phase shifter are positioned rearwardly of the reflector.

35-43. (canceled)
